(19) United States
(12) Patent Application Publication
(10) Pub. No.: US 2015/0162519 A1
(43) Pub. Date: Jun. 11, 2015

(54) APPARATUS AND METHOD FOR GENERATING SINUSODIAL WAVES, AND SYSTEM FOR DRIVING PIEZO ACTUATOR USING THE SAME

(71) Applicant: SAMSUNG ELECTRO-MECHANICS CO., LTD., Suwon-Si (KR)

(72) Inventors: Gyu Won KIM, Suwon-Si (KR); Joo Yul KO, Suwon-Si (KR)

(73) Assignee: SAMSUNG ELECTRO-MECHANICS CO., LTD., Suwon-Si (KR)

(21) Appl. No.: 14/245,815

(22) Filed: Apr. 4, 2014

(30) Foreign Application Priority Data
Dec. 5, 2013 (KR) 10-2013-0150480

(51) Int. Cl. H01L 41/04; H03B 28/00

(52) U.S. Cl. CPC H01L 41/042; H03B 28/00

(57) ABSTRACT

An apparatus for generating sinusoidal waves may include a look-up table storage unit including a plurality of sampling points determined based on a base frequency and a sampling frequency, a resolution scale unit loading the sampling points at a rate according to an input signal and calculating interpolation value data between the loaded sampling points so as to output the calculated interpolation value data along with the sampling points, and a sinusoidal wave generation unit generating a sinusoidal wave by using the sampling points and the interpolation value data

### CROSS-REFERENCE TO RELATED APPLICATION

This application claims the benefit of Korean Patent Application No. 10-2013-0150480 filed on Dec. 5, 2013, with the Korean Intellectual Property Office, the disclosure of which is incorporated herein by reference.

### BACKGROUND

The present disclosure relates to an apparatus and a method for generating sinusoidal waves, and a system for driving a piezoelectric actuator using the same.

As electronic device technology advances, various driving apparatuses are being developed for use therein, and signals having various wave forms are being used for such driving apparatuses.

In particular, in the case of haptic technology used in touch-based devices such as mobile terminals, it is important to precisely respond to user data inputs.

In the field of haptic technology, a piezoelectric actuator driven with signal having a sinusoidal waveform is used, and accordingly, it is necessary to generate the waveform of the sinusoidal wave with greater precision in order to drive the piezoelectric actuator precisely.

According to the technology for driving a piezoelectric actuator in the related art, in order to precisely generate a sinusoidal waveform, a look-up table storing high resolution digital values and a high resolution digital-to-analog converter are required.

According to the technology for driving a piezoelectric actuator in the related art, however, the size of a chip for generating a sinusoidal waveform is increased and the manufacturing costs are relatively high.

### SUMMARY

An exemplary embodiment in the present disclosure may provide an apparatus and a method for generating sinusoidal waves capable of generating high resolution sinusoidal waves with greater precision by calculating an interpolation value between digital values in a low resolution look-up table to generate a sinusoidal wave, and a system for driving a piezoelectric actuator using the same.

According to an exemplary embodiment in the present disclosure, an apparatus for generating sinusoidal waves may include: a look-up table storage unit including a plurality of sampling points determined based on a base frequency and a sampling frequency; a resolution scale unit loading the sampling points at a rate according to an input signal and calculating interpolation value data between the loaded sampling points so as to output the calculated interpolation value data along with the sampling points; and a sinusoidal wave generation unit generating a sinusoidal wave by using the sampling points and the interpolation value data.

The resolution scale unit may apply a weight according to a volume of the calculated interpolation value data.

The resolution scale unit may include: a register buffer unit loading adjacent sampling points; and a scale-up unit calculating interpolation value data between the adjacent sampling points.

The resolution scale unit may include a weighting unit applying a weight according to a volume of the calculated interpolation value data.

The look-up table storage unit may include 1,024 sampling points of the sampling frequency with respect to the base frequency.

The sinusoidal wave generation unit may include a digital-to-analog converter, and, upon receiving the sampling points and the interpolation value data from the resolution scale unit, output analog values corresponding thereto.

According to an exemplary embodiment in the present disclosure, a method for generating sinusoidal waves may include: storing a look-up table including a plurality of sampling points determined based on a base frequency and a sampling frequency; scaling up resolution by calculating interpolation value data between the sampling points and outputting the calculated interpolation value data along with the sampling points; and generating a sinusoidal wave by using the sampling points and the interpolation value data.

The look-up table may include 1,024 sampling points of the sampling frequency with respect to the base frequency.

The scaling up of the resolution may include: loading the sampling points at a rate according to an input signal; calculating interpolation value data between the sampling points; and outputting the sampling points and the interpolation value data.

The scaling up of the resolution may include applying a weight according to a volume of the interpolation value data, between the calculating of the interpolation value data and the outputting of the calculated interpolation value data along with the sampling points.

According to an exemplary embodiment in the present disclosure, a system for driving a piezoelectric actuator may include: a piezoelectric actuator operated by receiving a sinusoidal wave at both terminals thereof; and an apparatus for generating sinusoidal waves, the apparatus loading sampling points at a rate according to an input signal, calculating interpolation value data between the sampling points, generating a sinusoidal wave by using the sampling points and the interpolation value data, and providing the sinusoidal wave to the piezoelectric actuator.

The apparatus for generating sinusoidal waves may include: a look-up table storage unit including a plurality of sampling points determined based on a base frequency and a sampling frequency; a resolution scale unit loading the sampling points at a rate according to an input signal and calculating interpolation value data between the loaded sampling points so as to output the calculated interpolation value data along with the sampling points; and a sinusoidal wave generation unit generating a sinusoidal wave by using the sampling points and the interpolation value data.

The resolution scale unit may include: a register buffer unit loading adjacent sampling points; and a scale-up unit calculating interpolation value data between the adjacent sampling points.

The resolution scale unit may include a weighting unit applying a weight according to a volume of the calculated interpolation value data.

The look-up table storage unit may include 1,024 sampling points of the sampling frequency with respect to the base frequency.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a system for driving a piezoelectric actuator according to an exemplary embodiment of the present disclosure;

FIG. 2 is a block diagram illustrating an apparatus for generating sinusoidal waves according to an exemplary embodiment of the present disclosure;

FIG. 3 is a block diagram of an example of the resolution scale unit shown in FIG. 2;

FIG. 4 is a block diagram of an example of the sinusoidal wave generation unit;

FIG. 5 is a flowchart illustrating a method of generating sinusoidal waves according to an exemplary embodiment of the present disclosure; and

FIG. 6 is a block diagram of an example of the scaling up of resolution shown in FIG. 5.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

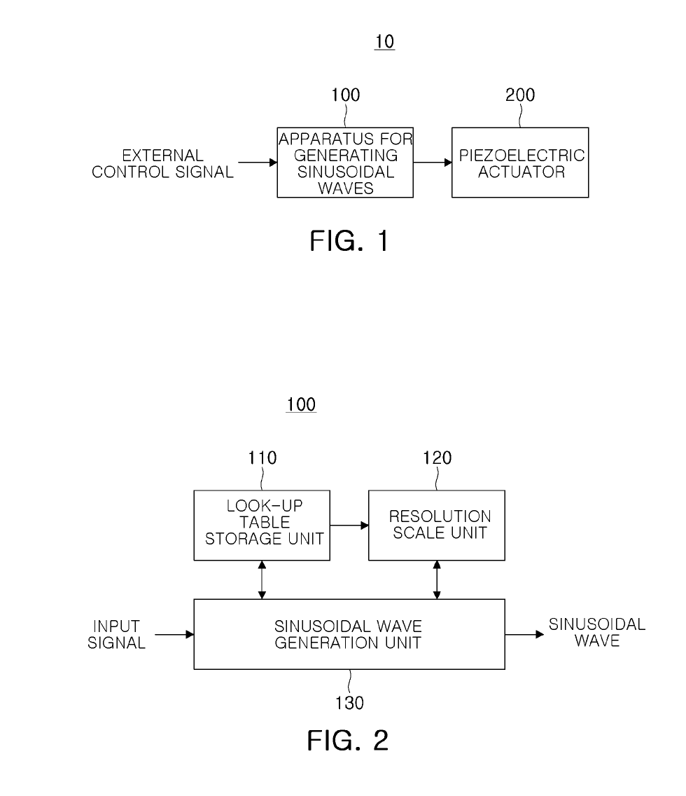

FIG. 1 is a block diagram of a system for driving a piezoelectric actuator according to an exemplary embodiment of the present disclosure.

Referring to FIG. 1, the system 10 for driving a piezoelectric actuator may include an apparatus for generating sinusoidal waves 100 and a piezoelectric actuator 200.

The apparatus for generating sinusoidal waves 100 may generate sinusoidal waves to drive the piezoelectric actuator 200 and may provide it to the piezoelectric actuator 200.

Accordingly, the apparatus for generating sinusoidal waves 100 may serve as an apparatus for driving the piezoelectric actuator 200.

Upon receiving an external control signal associated with sinusoidal waves to be generated (referred hereinafter to as “target frequency”), the apparatus for generating sinusoidal waves 100 may generate a sinusoidal wave at the target frequency.

The apparatus for generating sinusoidal waves 100 may generate sinusoidal waves using a look-up table.

The look-up table may include a plurality of sampling points determined based on a base frequency and a predetermined sampling frequency.

For example, in the case that the base frequency is 7.8125 Hz and the predetermined sampling frequency is 8 KHz, there may be 1,024 sampling points.

In this example, in the case that the target frequency is 8 KHz, values corresponding to 1,024 sampling points are obtained, and analog values (e.g., current) corresponding to the values are output, thereby generating a sinusoidal wave.

That is, the apparatus for generating sinusoidal waves 100 may load the sampling points from the look-up table having digital values stored therein, and then perform digital-analog conversion to thereby generate a sinusoidal wave.

That is, sampling points are loaded, interpolation value data between the loaded sampling points are calculated, and a sinusoidal wave may be generated using the calculated interpolation value data and the sampling points.

The piezoelectric actuator 200 may be operated by receiving at both terminals thereof the sinusoidal wave provided from the apparatus for generating sinusoidal waves 100.

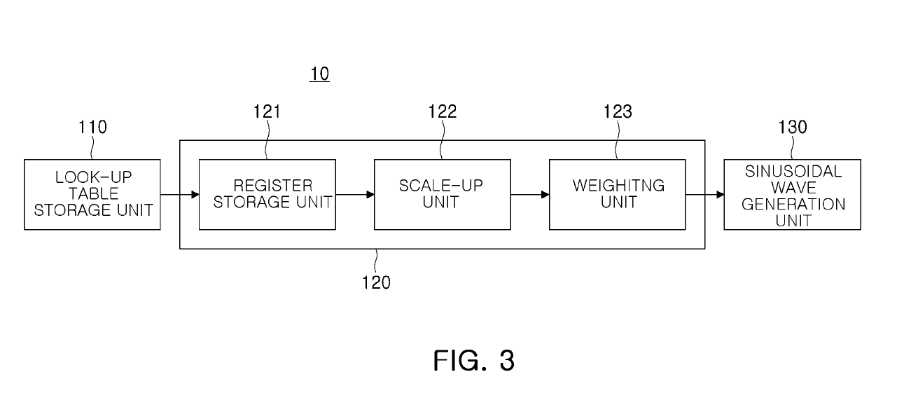

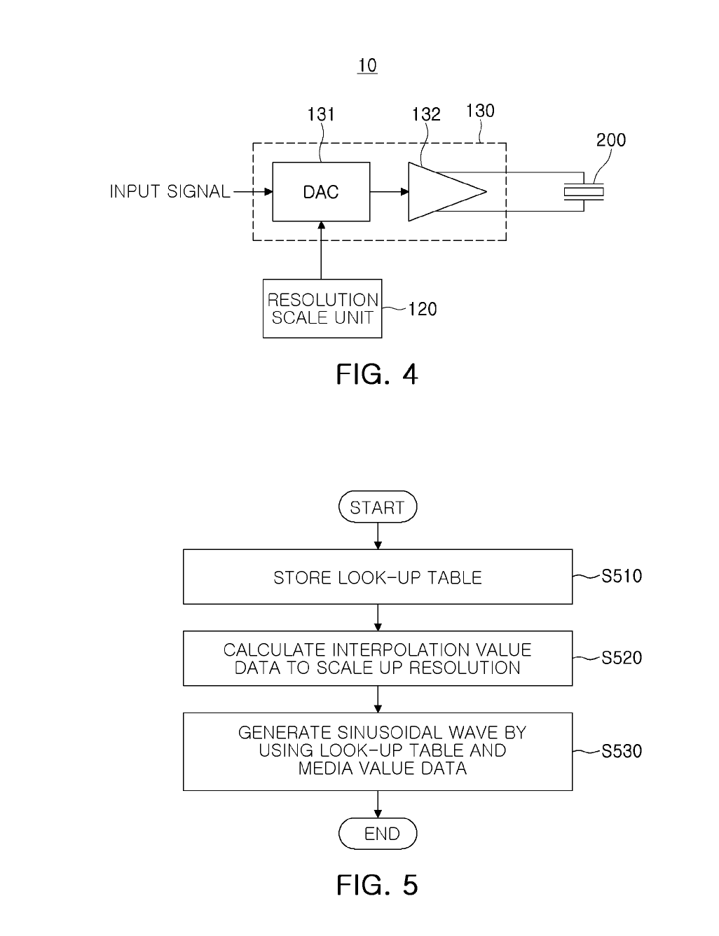

FIG. 2 is a block diagram of an apparatus for generating sinusoidal waves according to an exemplary embodiment of the present disclosure, FIG. 3 is a block diagram of an example of the resolution scale unit shown in FIG. 2, and FIG. 4 is a block diagram of an example of the sinusoidal wave generation unit shown in FIG. 2.

Hereinafter, apparatuses for generating sinusoidal waves according to various exemplary embodiments of the present disclosure will be described with reference to FIGS. 2 and 3.

The look-up table storage unit 110 may store a look-up table that includes a plurality of sampling points determined based on a base frequency and a sampling frequency.

In an exemplary embodiment of the present disclosure, the look-up table may include 1,024 sampling points of the sampling frequency with respect to the base frequency.

The resolution scale unit 120 may load the sampling points at a rate according to an input signal and may calculate interpolation value data between the loaded sampling points so as to output the loaded sampling points along with the sampling points.

Specifically, the resolution scale unit 120 may load sampling points from the look-up table storage unit 110 at a rate according to the input target frequency, and may calculate interpolation values between the loaded sampling points sequentially.

For example, assuming that first to third sampling points are loaded from the loop-up table storage unit 110, the resolution scale unit 120 may calculate first interpolation value data that interpolates between the first sampling point and the second sampling point and may calculate second interpolation value data that interpolates between the second sampling point and the third sampling point.

The resolution scale unit 120 may sequentially output the first sampling point, the first interpolation value data, the second sampling point, the second interpolation value data, and the third sampling point to the sinusoidal wave generation unit 130.

In an exemplary embodiment, interpolation value data may be an average value between two adjacent sampling points.

In an exemplary embodiment, the resolution scale unit 120 may apply a weight according to the volume of the calculated interpolation value data.

This is for more precisely generating sinusoidal waveforms. The resolution scale unit 120 may apply a higher weight for the interpolation value data having a larger volume which is calculated from the sampling points.

In other words, the resolution scale unit 120 may apply a higher weight to a sampling point which is closer to a peak or a trough of a sinusoidal waveform generated by the sinusoidal wave generation unit 130.

The sinusoidal wave generation unit 130 may generate a sinusoidal wave by using the sampling points received from the resolution scale unit 120 and interpolation value data.

Referring to FIG. 3, the resolution scale unit 120 may include a register buffer unit 121 and a scale-up unit 122.

The resolution scale unit 120 may further include a weighting unit 123.

The register buffer unit 121 may load adjacent sampling points from the look-up table 110.

The scale-up unit 122 may calculate interpolation value data between adjacent sampling points by using the sampling points loaded to the register buffer unit 121.

In an exemplary embodiment, the scale-up unit 122 may calculate an average value between adjacent sampling points as the interpolation value data.

The weighting unit 123 may apply a weight according to the volume of the calculated interpolation value data.

In an exemplary embodiment, the weighting unit 123 may apply a higher weight for the interpolation value data having a larger digital value which is calculated from the sampling points.

Referring to FIG. 4, the sinusoidal wave generation unit 130 may include a digital-to-analog converter 131 and an amplifier 132.

Upon receiving a digital value for the target frequency, the digital-to-analog converter 131 may output analog values corresponding to the sampling points corresponding to the target frequency.

The amplifier 132 may filter analog values output from the digital-to-analog converter 131 to generate a sinusoidal wave.

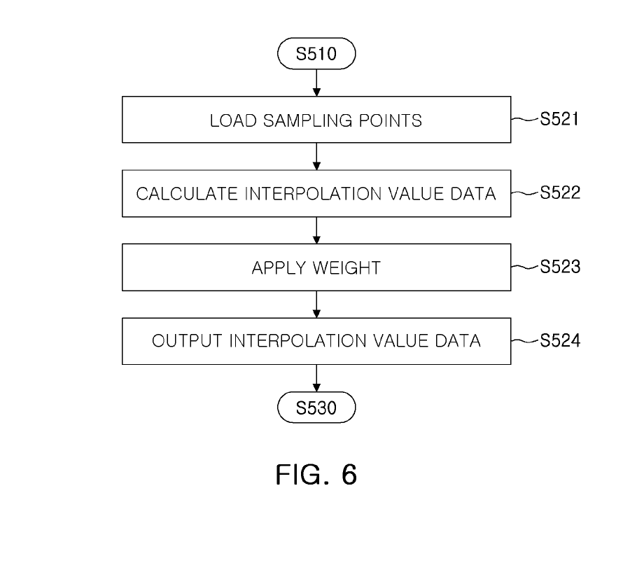

FIG. 5 is a flowchart for illustrating a method for generating sinusoidal waves according to an exemplary embodiment of the present disclosure, and FIG. 6 is a flowchart for illustrating the scaling up of resolution in the method illustrated in FIG. 5.

Referring to FIG. 5, the apparatus for generating sinusoidal waves 100 may store a look-up table that includes a plurality of sampling points determined based on the base frequency and sampling frequency (S510).

Then, the apparatus for generating sinusoidal waves 100 may calculate interpolation value data between sampling points to scale up resolution and may output it along with the sampling points (S520).

Then, the apparatus for generating sinusoidal waves 100 may generate a sinusoidal wave by using the sampling points and the interpolation value data (S530).

In an exemplary embodiment, the look-up table may include 1,024 sampling points of the sampling frequency with respect to the base frequency.

Now, examples of operation S520 will be described with respect to FIG. 6. The method for generating sinusoidal waves may include loading the sampling points at a rate according to an input signal (S521), calculating interpolation value data between the sampling points (S522), and outputting the sampling points and the interpolation value data (S524).

In another example of operation S520, the method for generating sinusoidal waves may further include applying a weight according to the volume of the interpolation value data (S523) between the calculating of the interpolation value data S522 and the outputting of the sampling points and the interpolation value data S524.

As set forth above, according to exemplary embodiments of the present disclosure, resolution may be scaled up even without a high resolution digital-to-analog converter, such that the size and cost of an apparatus for generating sinusoidal waves may be reduced, and sinusoidal waves may be generated more precisely.

While exemplary embodiments have been shown and described above, it will be apparent to those skilled in the art that modifications and variations could be made without departing from the spirit and scope of the present disclosure as defined by the appended claims.

What is claimed is:

1. An apparatus for generating sinusoidal waves, comprising:
a look-up table storage unit including a plurality of sampling points determined based on a base frequency and a sampling frequency;
a resolution scale unit configured to load the sampling points at a rate according to an input signal and calculate interpolation value data between the loaded sampling points so as to output the calculated interpolation value data along with the sampling points; and
a sinusoidal wave generation unit configured to generate a sinusoidal wave by using the sampling points and the interpolation value data.

2. The apparatus of claim 1, wherein the resolution scale unit applies a weight according to a volume of the calculated interpolation value data.

3. The apparatus of claim 1, wherein the resolution scale unit includes: a register buffer unit configured to load adjacent sampling points; and a scale-up unit configured to calculate interpolation value data between the adjacent sampling points.

4. The apparatus of claim 3, wherein the resolution scale unit includes a weighting unit applying a weight according to a volume of the calculated interpolation value data.

5. The apparatus of claim 1, wherein the look-up table storage unit includes 1,024 sampling points of the sampling frequency with respect to the base frequency.

6. The apparatus of claim 1, wherein the sinusoidal wave generation unit includes a digital-to-analog converter, and, upon receiving the sampling points and the interpolation value data from the resolution scale unit, outputs analog values corresponding thereto.

7. A method for generating sinusoidal waves, comprising:
storing a look-up table including a plurality of sampling points determined based on a base frequency and a sampling frequency;
scaling up resolution by calculating interpolation value data between the sampling points and outputting the calculated interpolation value data along with the sampling points; and
generating a sinusoidal wave by using the sampling points and the interpolation value data.

8. The method of claim 7, wherein the look-up table includes 1,024 sampling points of the sampling frequency with respect to the base frequency.

9. The method of claim 7, wherein the scaling up of the resolution includes:
loading the sampling points at a rate according to an input signal;
calculating interpolation value data between the sampling points; and
outputting the sampling points and the interpolation value data.

10. The method of claim 9, wherein the scaling up of the resolution further includes applying a weight according to a volume of the interpolation value data, between the calculating of the interpolation value data and the outputting of the calculated interpolation value data along with the sampling points.

11. A system for driving a piezoelectric actuator, comprising:
a piezoelectric actuator operated by receiving a sinusoidal wave at both terminals thereof; and
an apparatus for generating sinusoidal waves, the apparatus configured to load sampling points at a rate according to an input signal, calculate interpolation value data between the sampling points, generate a sinusoidal wave by using the sampling points and the interpolation value data, and provide the sinusoidal wave to the piezoelectric actuator.

12. The system of claim 11, wherein the apparatus includes:
a look-up table storage unit configured to include a plurality of sampling points determined based on a base frequency and a sampling frequency;
a resolution scale unit configured to load the sampling points at a rate according to an input signal and calculate interpolation value data between the loaded sampling points so as to output the calculated interpolation value data along with the sampling points; and
a sinusoidal wave generation unit configured to generate a sinusoidal wave by using the sampling points and the interpolation value data.

13. The system of claim 12, wherein the resolution scale unit includes: a register buffer unit configured to load adjacent sampling points; and a scale-up unit configured to calculate interpolation value data between the adjacent sampling points.

14. The system of claim 13, wherein the resolution scale unit includes a weighting unit configured to apply a weight according to a volume of the calculated interpolation value data.

15. The system of claim 12, wherein the look-up table storage unit includes 1,024 sampling points of the sampling frequency with respect to the base frequency.
